(19) United States
(12) Patent Application Publication
(10) Pub. No.: US 2026/0309825 A1
(43) Pub. Date: Oct. 8, 2026

(54) CINE MRI PHANTOM

(71) Applicants: MODUS MEDICAL DEVICES INC., London (CA); WASHINGTON UNIVERSITY, St. Louis, MO (US)

(72) Inventors: Taeho KIM, St. Louis, MO (US); Shanti Marasini, St. Louis, MO (US); Michael Cole, London (CA); Rocco Flores, London (CA)

(21) Appl. No.: 19/482,585

(22) PCT Filed: May 10, 2024
(86) PCT No.: PCT/CA2024/050632

§ 371 Date: Nov. 7, 2025

Related U.S. Application Data
(60) Provisional application No. 63/465,642, filed on May 11, 2023.

(51) Int. Cl. G01R 33/58; G01R 33/563

(52) U.S. Cl. CPC G01R 33/58; G01R 33/56325

(57) ABSTRACT

A cine imaging phantom having a housing made of a rigid material containing one or more sealed reservoirs containing a fluid material. The one or more sealed reservoirs define an outer reservoir and an inner reservoir, located within the outer reservoir. The outer reservoir is in the shape of a cylinder and the inner reservoir is in the shape of a sphere. The inner reservoir is located concentrically within the outer reservoir. An isocentre indicator is positioned within the inner reservoir at its centre.

### FIELD OF THE INVENTION

The present invention relates to an imaging quality assurance (QA) phantom apparatus and, in particular, to an imaging phantom for cinema (cine) magnetic resonance imaging (MRI).

### BACKGROUND

2D-cine MRI is clinically used in cardiology and MR-guided radiotherapy for motion evaluation. Additionally, 3D-cine MRI (or pseudo-3D-cine MRI, using orthogonal cine imaging) is emerging as imaging equipment and techniques improve, as a useful clinical tool. However, the image resolution in cine MRI is often limited due to fast acquisition. As a result, the evaluation of the image quality of these low-resolution images is challenging using regular MRI phantoms, which are generally intended for higher-resolution images.

Accordingly there is a need for MRI quality assurance phantoms specifically designed to produce useful image quality measurements, within the low-resolution imaging constraints of 2D or 3D-cine MRI.

### SUMMARY OF THE INVENTION

A cine imaging phantom, according to the present invention, has a housing made of a rigid material containing one or more sealed reservoirs containing a fluid material. The one or more sealed reservoirs define an outer reservoir and an inner reservoir, located within the outer reservoir.

In another embodiment, the outer reservoir is in the shape of a cylinder and the inner reservoir is in the shape of a sphere. The inner reservoir is located concentrically within the outer reservoir.

In another embodiment, the housing comprises a cylindrical shell and two end plates attached at either end of the cylindrical shell.

### BRIEF DESCRIPTION OF THE DRAWINGS

In order that the invention may be more clearly understood, a preferred embodiment thereof will now be described in detail by way of example, with reference to the accompanying drawings, in which:

FIG. 1 is a side view of a cine imaging phantom, according to the present invention.

FIG. 2 is an end view of the phantom of FIG. 1.

FIG. 3 is a side view of the inner portion of the phantom shown in FIG. 1.

FIG. 4 is an end view of the inner portion of the phantom shown in FIG. 1.

FIG. 5 is a side detail view of the solid sphere of the inner portion of the phantom shown in FIG. 3.

FIG. 6 is a cross-sectional view of the solid sphere, along the lines A-A in FIG. 5.

FIG. 7 is a side detail view of the isocentre indicator of inner portion of the phantom shown in FIG. 6.

FIG. 8 is an axial MR image of the phantom shown in FIG. 1, showing the outer cylinder, the inner sphere, and the isocentre indicator.

FIG. 9A is a polar plot of the image distortion for the inner sphere from the axial MR image shown in FIG. 8.

FIG. 9B is a polar plot of the image distortion for the outer cylinder from the axial MR image shown in FIG. 8.

### DESCRIPTION OF THE PREFERRED EMBODIMENT

A 2D or 3D-cine imaging phantom, according to the present invention, is a container made of a rigid material with a known geometry, containing one or more sealed reservoirs containing a fluid (signal producing) material. The one or more sealed reservoirs define a two-shell shape within the phantom with a known geometry that permits image quality analysis from rapid acquisition (low resolution) cine images. The present phantom design permits at least three different image quality measurements to be made: (1) plane location verification; (2) signal uniformity; and (3) image distortion.

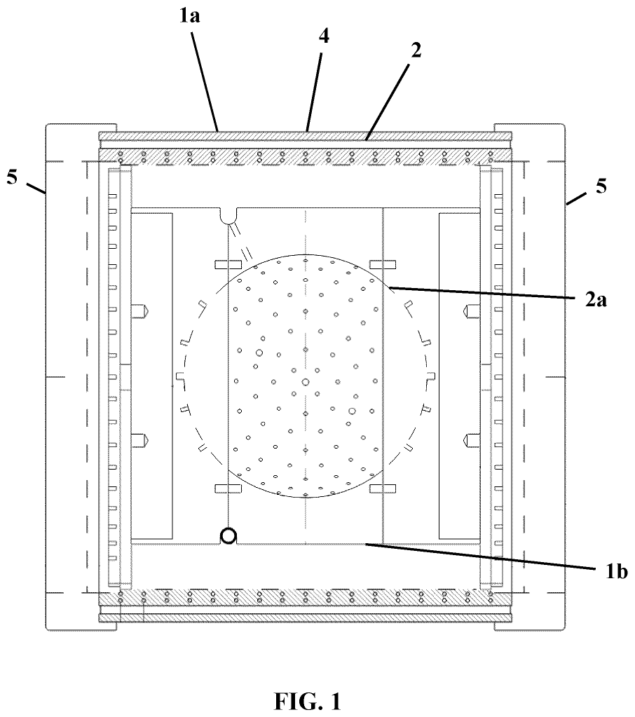

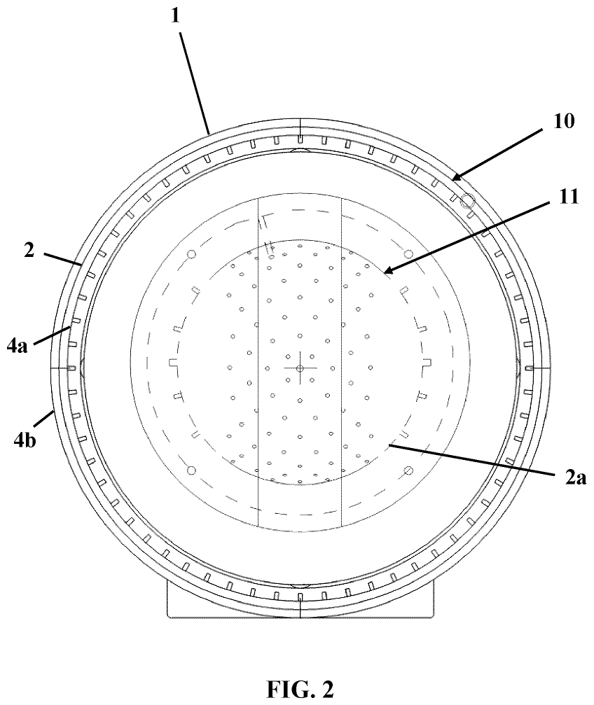

As shown in FIGS. 1 and 2, the cine imaging phantom has a housing 1 and one or more sealed reservoirs 2. The rigid material of the housing 1 and the fluid material in the sealed reservoirs 2 are susceptibility matched to one another to minimize susceptibility gradient induced distortion at the boundary between the different materials. Preferably, the fluid material is mineral oil or an aqueous solution with a close susceptibility match to human tissue, doped with one or more suitable T1 and T2 relaxivity modifiers, and the rigid material is acrylic, although various materials may be used for MRI or other imaging modalities.

As shown in FIG. 1, the housing 1 is made up of a cylindrical shell 4 and two end plates 5, which are attached on either end of the cylindrical shell 4. The cylindrical shell 4 and end plates 5 have inner and outer walls 4a and 4b, and 5a and 5b, respectively. Therebetween, the cylindrical shell 4 and end plates 5 each define a sealed reservoir 2. Preferably, the cylindrical shell 4 and one of the end plates 5 contain one continuous sealed reservoir 2, while the other end plate 5 contains a separate sealed reservoir 2. The one or more sealed reservoirs defined by the cylindrical shell 4 provide a fluid volume in the shape of an outer cylinder 10.

The housing 1 extends into the interior of the cylindrical shell 4 and defines another, or another portion of the same, sealed reservoir 2a within the cylindrical shell 4. Preferably, the sealed reservoir 2a is in the shape of an inner sphere 11, located centrally within the cylindrical shell 4 and between the two end plates 5, and is smaller in size than the cylindrical shell 4. Alternatively, the sealed reservoir 2a may be located off-centre or may have an size closer to that of the cylindrical shell 4, or both.

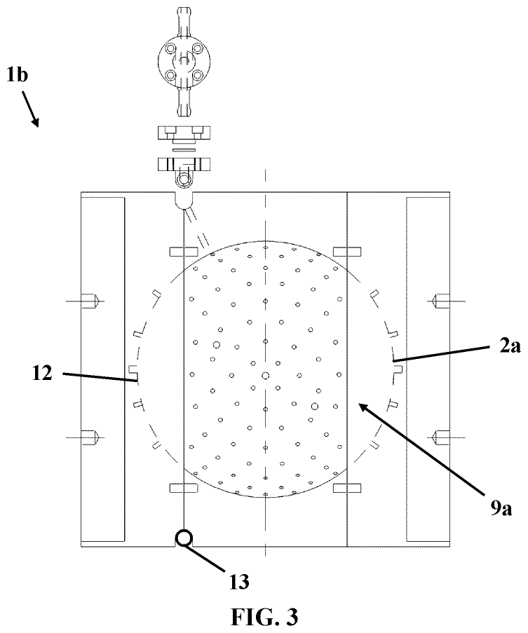

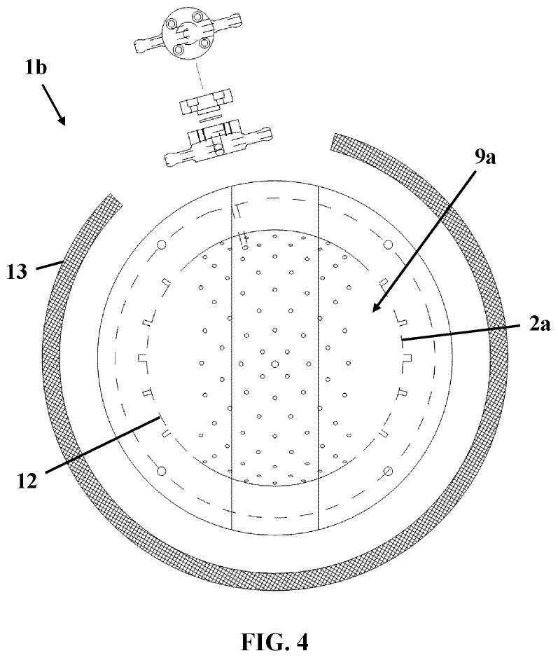

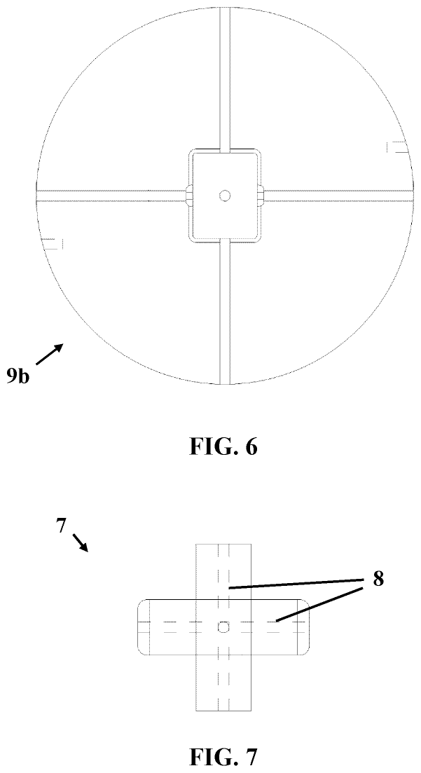

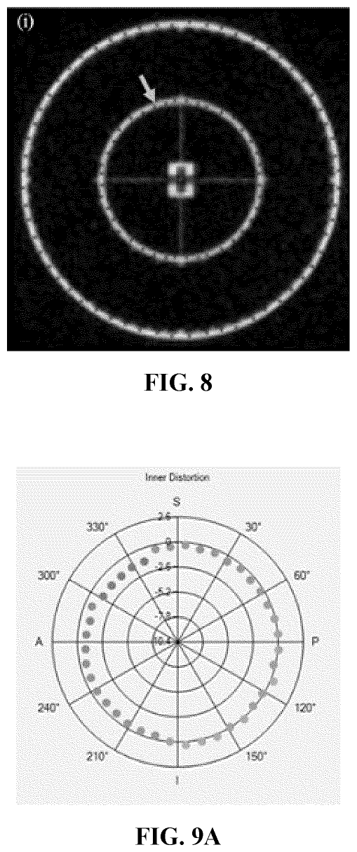

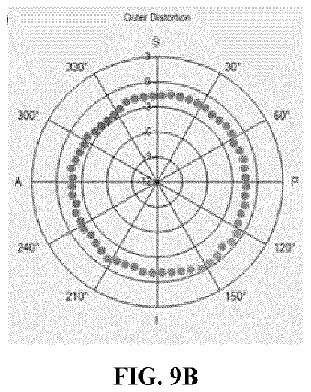

As shown in FIGS. 3 and 4, the sealed reservoir 2a is separate from the sealed reservoirs 2 defined by the cylindrical shell 4 and the end plate(s) 5. Alternatively, the housing 1 may define a single sealed reservoir 2 that defines both an outer cylinder 10 between the inner and outer walls 4a and 4b of the cylindrical shell 4 and an inner sphere 11 located within the cylindrical shell 4. As shown in FIGS. 2 and 8, the diameter of the inner sphere 11 is, preferably, about half that of the outer cylinder 10. As shown in FIGS. 3-6, the inner sphere 11 is a hollow sphere defined by the sealed reservoir 2a formed in the housing 1, between a spherical recess 9a in the housing 1 and a solid sphere 9b (shown in FIG. 9) positioned within the recess 9a. Preferably, the sealed reservoir 2a that defines the inner sphere 11 has a thickness equal to the thickness of the one or more sealed reservoirs 2 that define the outer cylinder 10.

The housing 1, preferably, has two main components: an outer portion la, which is made up of the cylindrical shell 4 and defines the outer cylinder 10, and an inner portion 1b, which is made up of an interior extension of the housing 1 or an insert and defines the inner sphere 11. This configuration of phantom may also be described as a “phantom within a phantom”, where the cylindrical shell 4 and end plates 5 make up a first phantom, and a separate housing 1 containing the sealed reservoir 2a makes up a second phantom. Although FIG. 1 shows both end plates 5 as solid caps, either or both end plates 5 may have one or more apertures therethrough to permit the second phantom to be inserted into position within the first phantom.

As shown in FIGS. 1 and 2, the inner portion 1b of the housing 1 may be smaller than the cylindrical shell 4, such that it is spaced apart from the inner wall 4a when mounted within the cylindrical shell 4. In this configuration, the inner portion 1b of the housing 1 may be mounted to one or both of the end plates 5. Alternatively, the outer portion la of the housing 1 may be a solid cylinder, except for the sealed reservoir 2 defining the outer cylinder 10, with a recess formed therein to receive the inner portion 1b, as an insert.

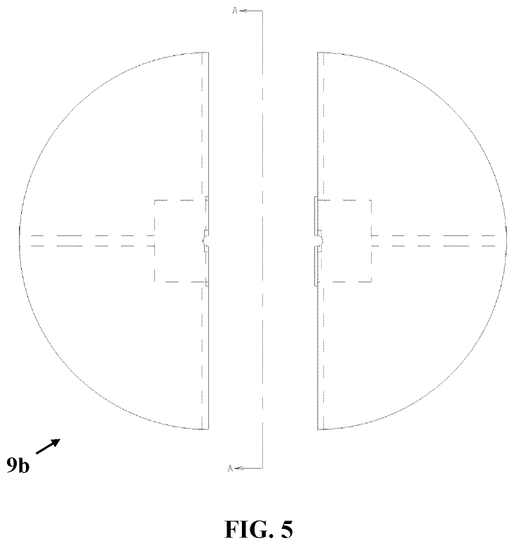

As shown in FIGS. 5-7, an isocentre indicator 7 may be located within the housing 1 to detect misalignment of the image. The isocentre indicator 7 is a generally square block of acrylic with three orthogonal apertures 8 that cross in the centre of the isocentre indicator 7 and extend between the midpoints of the four opposing side edges. The apertures 8 of the isocentre indicator 7 are sized to permit a signal to be detected through the apertures 8, for example, they may be 3 mm in diameter to facilitate detection with most imaging systems.

In any configuration, the cine imaging phantom is configured to present imaging structures arranged as two concentric shells. These imaging structures are presented by the fluid contained in the one or more sealed reservoirs 2, which are in the shape of an outer cylinder 10 and an inner sphere 11, with an optional isocentre indicator 7. The phantom may be scanned in any of one to three orthogonal planes, using MRI or other imaging systems. The phantom images may then be analy zed using automated image analysis software to produce principal component error values at points around the phantom's concentric shells as well as image isocentre alignments based on the isocentre indicator 7. This allows for the effective evaluation of imaging distortion and isocentre shift in cine imaging on imaging systems, such as MRI and MRI-Linac systems.

As discussed above, the cine imaging phantom of the present invention permits at least three image quality measurements to be made, namely: (1) plane location verification; (2) signal uniformity; and (3) image distortion. The plane location (of measurement) may be verified by offsetting the plane location from the centre of the phantom and matching the measured dimensions of the image with the expected radius of the inner sphere 11, compared to the outer cylinder 10. For any given offset position, the radius of the outer cylinder 10 should remain consistent, while the radius of the inner sphere 11 will vary inversely with the offset distance from isocentre. The signal uniformity of the image may be measured by comparing the signal strength at various positions about the perimeter of the inner sphere 11 and (at least for measurements in the axial plane) the outer cylinder 10. Since the thickness of the sealed reservoir(s) 2 and 2a are consistent, the measured signal strength should also be consistent throughout the image. The image distortion can be measured by measuring deviations from the circular shape of the inner sphere 11 and (at least for measurements in the axial plane) the outer cylinder 10, as shown in the axial MR image and polar plots of image distortion shown in FIGS. 8, 9A, and 9B.

Optionally, the cine phantom may be configured with temperature and pressure compensation, as described in U.S. Pat. No. 10,310,048 B2, such that each sealed reservoir has a first volume portion and a second variable volume portion in fluid communication therewith to accommodate temperature-induced fluctuations in pressure of the fluid in the sealed reservoir 2. As shown in FIGS. 3-6, the sealed reservoir 2a that defines the inner sphere 11 has a first volume portion 12 and a second variable volume portion 13. The first volume portion 12 is contained within the portion of the housing 1 that defines the inner sphere 11. The second variable volume portion 13 is contained within a flexible length of tubing that extends around the perimeter of the cylindrical shell 4. Alternatively, the second variable volume portion 13 may be provided by way of an expandable bladder, or other expandable chamber or structure, as long as it is in fluid communication with the first volume portion 12 and can expand or contract in response to changes in volume of the fluid filling the sealed reservoir 2a.

As a further option, additional image quality measurement structures may be added or incorporated into the cine phantom to provide a greater range of imaging analysis to be performed on the same phantom. For example, laser landmark targets or fiducials or both may be provided to facilitate alignment of the phantom in the imaging system. The interior surface of any of the one or more sealed reservoirs 2 may be provided with defined patterns or structures, such as a grid, to facilitate MRI image quality testing and permit more precise measurement of geometric distortion than is possible with just measurement of the shape of the inner sphere 11 and outer cylinder 10. Other similar imaging structures may include: modulation transfer function (MTF) resolution structures, slice thickness ramps, or multi-modality imaging targets, among other imaging or dosimetry targets or detectors.

The present invention has been described and illustrated with reference to an exemplary embodiment, however, it will be understood by those skilled in the art that various changes may be made and equivalents may be substituted for elements thereof without departing from the scope of the invention as set out in the following claims. Therefore, it is intended that the invention not be limited to the particular embodiments disclosed herein.

What is claimed is:

1. A cine imaging phantom, comprising a housing made of a rigid material containing one or more sealed reservoirs containing a fluid material, wherein the one or more sealed reservoirs define an outer reservoir and an inner reservoir located within the outer reservoir.

2. The cine imaging phantom of claim 1, wherein the outer reservoir is in the shape of a cylinder and the inner reservoir is in the shape of a sphere.

3. The cine imaging phantom of claim 2, wherein the housing comprises a cylindrical shell and two end plates attached at either end of the cylindrical shell.

4. The cine imaging phantom of claim 3, wherein the cylindrical shell and end plates have inner and outer walls which define a sealed reservoir therebetween.

5. The cine imaging phantom of claim 4, wherein the inner and outer walls of the cylindrical shell and one of the two end plates define a first sealed reservoir and the inner and outer walls of the other end plate define a second sealed reservoir.

6. The cine imaging phantom of claim 5, wherein the inner wall defining one of the first sealed reservoir or the second sealed reservoir extends into the space within the housing interior to the first sealed reservoir and forms an exterior wall defining the inner reservoir.

7. The cine imaging phantom of claim 5, wherein housing comprises a spherical recess and a solid sphere positioned within the recess, which define the inner reservoir therebetween.

8. The cine imaging phantom of claim 7, wherein the inner reservoir is located concentrically within the outer reservoir.

9. The cine imaging phantom of claim 8, wherein the inner reservoir and outer reservoir are in fluid communication with each other.

10. The cine imaging phantom of claim 8, wherein the inner reservoir is not in fluid communication with the outer reservoir.

11. The cine imaging phantom of claim 8, wherein an isocentre indicator is positioned within the inner reservoir at its centre.

12. The cine imaging phantom of claim 11, wherein the isocentre indicator is made of a rigid material and has three orthogonal apertures therethrough which cross at the centre of the inner reservoir.

13. The cine imaging phantom of claim 2, wherein the housing comprises an inner portion and an outer portion, wherein the inner portion is spaced apart from the outer portion, and wherein the inner reservoir is located within the inner portion.

14. The cine imaging phantom of claim 13, wherein the outer portion comprises a cylindrical shell and two end plates attached at either end of the cylindrical shell.

15. The cine imaging phantom of claim 14, wherein housing comprises a spherical recess and a solid sphere positioned within the recess, which define the inner reservoir therebetween.

16. The cine imaging phantom of claim 15, wherein the inner reservoir is located concentrically within the outer reservoir.

17. The cine imaging phantom of claim 16, wherein the inner reservoir and outer reservoir are in fluid communication with each other.

18. The cine imaging phantom of claim 16, wherein the inner reservoir is not in fluid communication with the outer reservoir.

19. The cine imaging phantom of claim 16, wherein an isocentre indicator is positioned within the inner reservoir at its centre.

20. The cine imaging phantom of claim 19, wherein the isocentre indicator is made of a rigid material and has three orthogonal apertures therethrough which cross at the centre of the inner reservoir.
